(19) United States
(12) Patent Application Publication
(10) Pub. No.: US 2009/0085136 A1
(43) Pub. Date: Apr. 2, 2009

(54) Image sensor and method for manufacturing the same

(76) Inventor: Chang Eun Lee, Mapo-gu (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/235,020

(22) Filed: Sep. 22, 2008

(30) Foreign Application Priority Data
Sep. 27, 2007 (KR) 10-2007-0097284

(51) Int. Cl. H01L 31/0232; H01L 31/18

(52) U.S. Cl. 257/432; 438/69; 257/E31.127

(57) ABSTRACT

An image sensor and method of manufacturing the same are provided. The image sensor can comprise a photodiode region an interlayer dielectric, and a microlens. The interlayer dielectric can have a trench over the photodiode region, and the microlens can be disposed in the trench such that the microlens fills the trench.

### CROSS-REFERENCE TO RELATED APPLICATION

The present application claims the benefit under 35 U.S.C. §119 of Korean Patent Application No. 10-2007-0097284, filed Sep. 27, 2007, which is hereby incorporated by reference in its entirety.

### BACKGROUND

A related art complementary metal oxide semiconductor (CMOS) image sensor typically includes a photodiode region for sensing light and a transistor circuitry region for converting the sensed light into electric signals.

Although it is a goal to increase the fill factor of an image sensor to improve optical sensitivity, the fill factor is generally limited by the fact that a transistor circuitry region is present in a pixel region with the photodiode.

In an attempt to improve the optical sensitivity of an image sensor, methods have been developed for forming a microlens, which concentrates incident light onto the photodiode region.

However, according to related art methods, various layers are typically present under the microlens, including an interlayer dielectric and/or a passivation. Thus, incident light passing through the microlens must also pass through an inter-metal interlayer dielectric, thereby reducing the intensity of the light. Additionally, signal distortion can be caused by the difference in refractive index after the light passes through the inter-metal interlayer dielectric.

Thus, there exists a need in the art for an improved image sensor and manufacturing method thereof.

### BRIEF SUMMARY

Embodiments of the present invention provide an image sensor and a manufacturing method thereof, which can inhibit light loss and signal distortion typically present in a related art image sensor caused by an interlayer dielectric present between a photodiode and a microlens.

In one embodiment of the present invention, an image sensor can comprise: a photodiode region on a substrate; an interlayer dielectric on the substrate and comprising a trench over the photodiode region; and a microlens in the trench. The microlens can fill the trench.

In another embodiment, a method for manufacturing an image sensor can comprise: forming a photodiode region on a substrate; forming an interlayer dielectric on the substrate; forming a trench in the interlayer dielectric over the photodiode region by removing a portion of the interlayer dielectric over the photodiode region; and forming a microlens in the trench. The microlens can be formed filling the trench.

The details of one or more embodiments are set forth in the accompanying drawings and the detailed description below. Other features will be apparent from the detailed description, the drawings, and the claims.

### BRIEF DESCRIPTION OF THE DRAWINGS

FIG. 1 is a cross-sectional view illustrating an image sensor according to an embodiment of the present invention.

FIGS. 2 to 5 are cross-sectional views illustrating a method for manufacturing an image sensor according to an embodiment of the present invention.

### DETAILED DESCRIPTION

Hereinafter, an image sensor and a method for manufacturing the same according to embodiments of the present invention will now be described in detail with reference to the accompanying drawings.

When the terms “on” or “over” are used herein, when referring to layers, regions, patterns, or structures, it is understood that the layer, region, pattern, or structure can be directly on another layer or structure, or intervening layers, regions, patterns, or structures may also be present. When the terms “under” or “below” are used herein, when referring to layers, regions, patterns, or structures, it is understood that the layer, region, pattern, or structure can be directly under the other layer or structure, or intervening layers, regions, patterns, or structures may also be present.

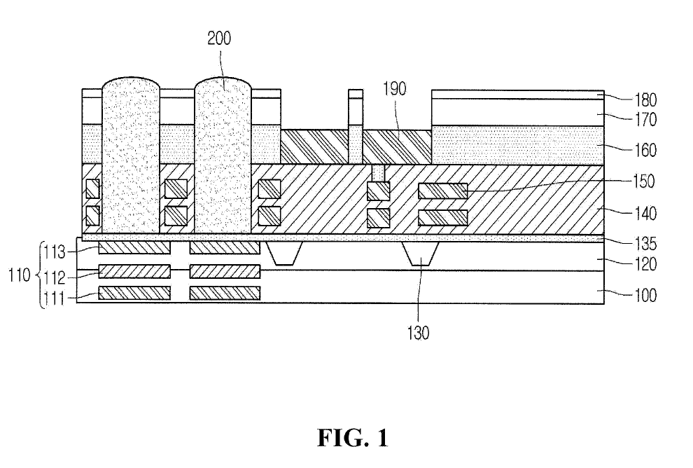

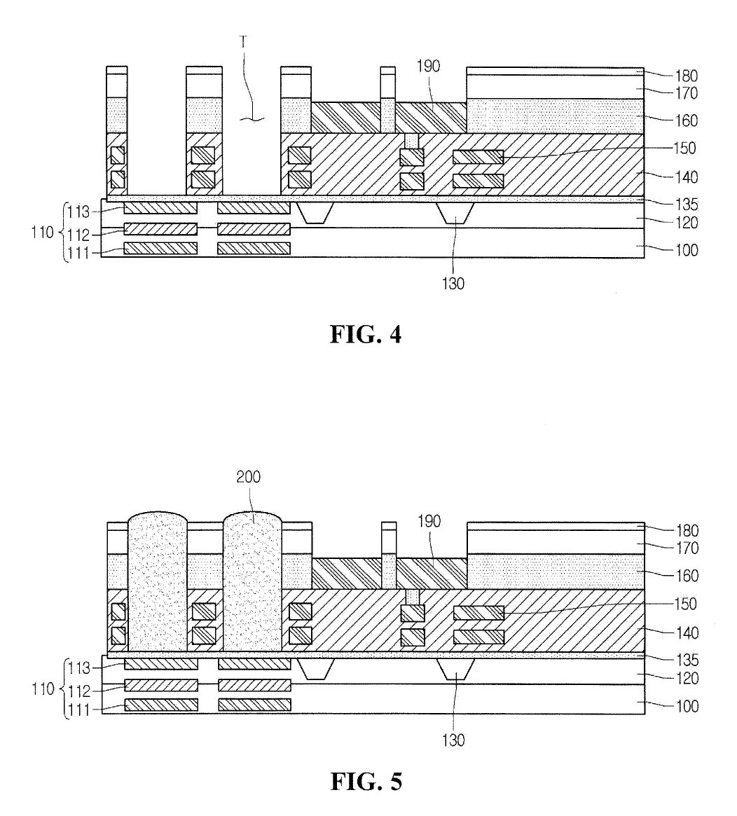

Referring to FIG. 1, an image sensor according to an embodiment of the present invention can include a photodiode region 110, an interlayer dielectric 140, and a microlens 200. The photodiode region 110 can be disposed on a substrate 100. The interlayer dielectric 140 can be disposed on the substrate 100 and can include a trench (reference letter T in FIG. 4). The microlens 200 can fill the trench. The microlens can be formed of any suitable material known in the art, for example, a photoresist. In an embodiment, the trench can be provided such that there is approximately no interlayer dielectric directly under the microlens 200. The image sensor can also include a transistor circuitry region (not shown) on the substrate 100 and device isolation layers 130.

In an embodiment, a light-blocking layer 180 can be provided on the interlayer dielectric 140 (such that the light-blocking layer 180 is not provided on the microlens 200) to inhibit crosstalk between adjacent pixels. The light-blocking layer 180 can comprise, for example, a green color filter photoresist or a dark material layer.

In an embodiment, the photodiode region 110 can include a vertical-type photodiode, providing photodiodes at different depths for receiving different wavelengths of light. These photodiodes can be referred to as color photodiodes. The photodiode region can include any suitable number of color photodiodes known in the art. For example, the photodiode region 110 can include a first color photodiode 111, a second color photodiode 112, and a third color photodiode 113, and each color photodiode can be a different color photodiode (e.g., the first color photodiode 111 can be a red photodiode, the second color photodiode 112 can be a green photodiode, and the third color photodiode 113 can be a blue photodiode). However, embodiments of the present invention are not limited thereto. Additionally, a color filter layer can be omitted, allowing the interlayer dielectric 140 on the photodiode region 110 to be more easily removed and the microlens 200 to be closer to the photodiode.

Additionally, in an embodiment, the image sensor can comprise metal interconnections 150 in the interlayer dielectric 140, a first passivation layer 160, and a metal pad 190. In a further embodiment, the image sensor can also comprise a second passivation layer 170. For example, the first passivation layer 160 can be an oxide passivation layer, and the second passivation layer 170 can be a nitride passivation layer.

In yet a further embodiment, the image sensor can also comprise an etch stop layer 135 on the photodiode region 110 and under the microlens 200.

An image sensor according to embodiments of the present invention can inhibit light loss and signal distortion by removing approximately all of the interlayer dielectric between the photodiode region and the microlens via the trench. In addition, by including a vertical-type photodiode, the color filter layer can be omitted. Therefore, the number of processes for manufacturing an image sensor can be reduced.

Additionally, according to an embodiment of the present invention, a light-blocking layer 180 can be provided above the interlayer dielectric 140. Thus, crosstalk between adjacent pixels and signal loss typically present in a related art image sensor can be inhibited.

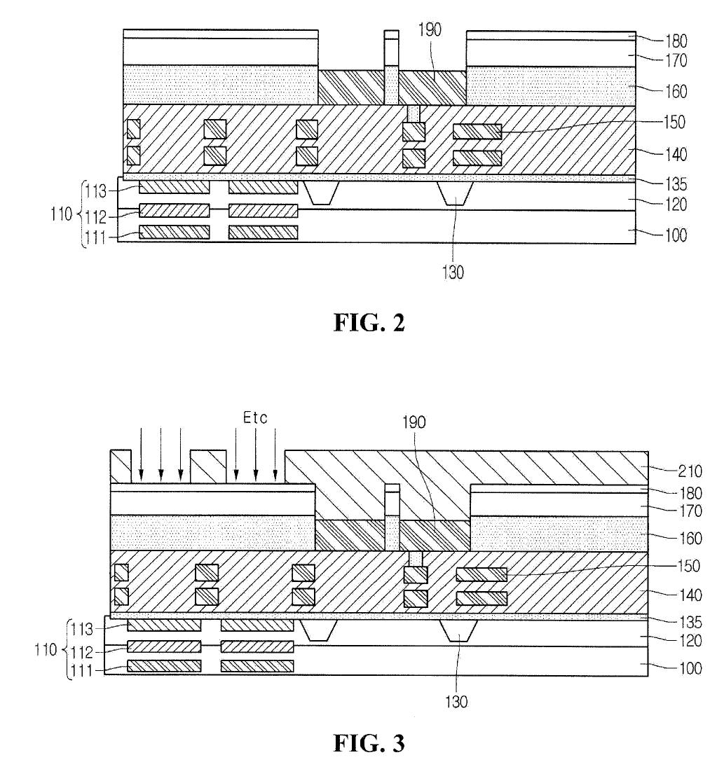

Hereinafter, a method for manufacturing an image sensor according to an embodiment of the present invention will now be described with reference to FIGS. 2 to 5.

Referring to FIG. 2, a first color photodiode 111 can be formed on a substrate 100. Additionally, any suitable number of color photodiodes can be sequentially formed on the substrate 100. For example, a first color photodiode 111, a second color photodiode 112, and a third color photodiode 113 can be sequentially formed on the substrate 100. However, embodiments of the present invention are not limited thereto.

In one embodiment, the substrate 100 can be a p-type epi substrate, and n-type ions can be implanted into the substrate 100 to form the first color photodiode 111, which can be, for example, a red photodiode. Then, n-type ions can be implanted in the substrate 110 to form a first plug (not shown) electrically connected to the first color photodiode 111.

Then, in an embodiment, a p-type first epi layer 120 can be formed on the substrate 100, and n-type ions can be implanted into the first epi layer 120 to form the second color photodiode 112, which can be, for example, a green photodiode. In a further embodiment, the third color photodiode 113, which can be, for example, a blue photodiode, can be formed in the surface of the first epi layer 120. A second plug (not shown) can be formed electrically connected to the second color photodiode 112 by implanting n-type ions.

Thereafter, in one embodiment, a device isolation layer 130 of the first epi layer 120 can be formed, and a transistor circuitry region (not shown) for transmitting and processing signals can be formed. The device isolation layer 130 of the first epi layer 120 can be formed to isolate active areas for each pixel of the image sensor. The transistor circuitry can be connected to the first color photodiode 111 and the second color photodiode 112 using the first plug and the second plug.

Next, an interlayer dielectric 140 can be formed on the substrate 100, and then multilayered metal interconnections 150 can be formed in the interlayer dielectric 140. Although two metal layers of interconnections 150 are illustrated in the figures, embodiments are not limited thereto.

Then, in an embodiment, a first passivation layer 160 can be formed on the interlayer dielectric 140 to protect the image sensor from moisture and/or external physical impact. Additionally, a second passivation layer 170 can be formed on the first passivation layer 160. For example, the first passivation layer 160 can be an oxide passivation layer, and the second passivation layer 170 can be a nitride passivation layer.

In a further embodiment, a metal pad 190 can be formed on the interlayer dielectric 140. The metal pad 190 can be formed using any suitable method known in the art. Also, the metal pad 190 can be heat-treated at a temperature ranging from about 400° C. to about 500° C.

Next, a light-blocking layer 180 can be formed on the first passivation layer 160 or the second passivation layer 170. The light-blocking layer 180 can inhibit crosstalk between adjacent pixels.

For example, the light-blocking layer 180 can comprise a green color filter photoresist or a dark material layer. In embodiments where the light-blocking layer 180 comprises the green color filter photoresist, the convenience and economy of the manufacturing process can be improved and crosstalk between pixels can be inhibited.

In embodiments where the light-blocking layer comprises a dark material layer, the light-blocking layer 180 can be formed of, for example, black glass. The light-blocking layer 180 can be formed by applying glass paste mixed with at least one kind of black pigment and then performing a sintering process. In one embodiment, a Fe—Cr—Co based first black pigment and a Cu—Cr based second black pigment can be used. The mixing ratio of the first black pigment and the second black pigment can be a weight ratio of, for example, about 5:4. The Fe—Cr—Co based first black pigment can help reduce ultraviolet light and visible light, and the Cu—Cr based second black pigment can reduce infrared light. Thus, the light-blocking layer 180 can reduce light in a wide range of wavelengths, including ultraviolet, visible, and infrared light.

Then, referring to FIG. 3, a photoresist pattern 210 can be formed such that the photoresist pattern 210 is not present over the photodiode region 110.

Referring to FIG. 4, the interlayer materials (which can include, for example, the light-blocking layer 180, the second passivation layer 170, the first passivation layer 160, and the interlayer dielectric 140) can be etched using the photoresist pattern 210 as an etching mask to form trench T over the photodiode region 110. The interlayer materials can be etched, for example, using an isotropic etching process.

In an embodiment, an etch stop layer 135 can be formed on the photodiode region 110 before forming the interlayer dielectric 140 to protect the photodiode region 110 during the etching process when the trench T is formed.

Referring to FIG. 5, a photoresist can be formed in the trench T to form the microlens 200. The photoresist can be filled in the trench T through coating, for example. The microlens 200 can be formed such that it fills the trench T. In one embodiment, the photoresist can completely fill the trench T and extend a portion above the trench T. According to an embodiment, a patterning and reforming process can be omitted by the forming of the photoresist to fill the trench.

According to embodiments of the present invention, the number of processes for manufacturing an image sensor can be reduced while inhibiting crosstalk between adjacent pixels and also inhibiting signal loss typically present in a related art image sensor.

In embodiments of the present invention, a vertical-type photodiode can be used, and approximately all of the interlayer dielectric between the photodiode region and the microlens can be removed, thereby inhibiting light loss and signal distortion.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An image sensor, comprising:
a photodiode region on a substrate;
an interlayer dielectric on the substrate and comprising a trench over the photodiode region; and
a microlens in the trench, wherein the microlens fills the trench.

2. The image sensor according to claim 1, further comprising a light-blocking layer on the interlayer dielectric.

3. The image sensor according to claim 2, wherein the light-blocking layer is provided around edges of the microlens.

4. The image sensor according to claim 2, wherein the light-blocking layer comprises a green color filter photoresist.

5. The image sensor according to claim 2, wherein the light-blocking layer comprises a dark material layer.

6. The image sensor according to claim 1, wherein the microlens comprises a photoresist.

7. The image sensor according to claim 1, further comprising an etch stop layer on the photodiode region and under the microlens.

8. The image sensor according to claim 1, wherein the photodiode region comprises a first color photodiode, a second color photodiode, and a third color photodiode.

9. The image sensor according to claim 8, wherein the first color photodiode is a red photodiode, the second color photodiode is a green photodiode, and the third color photodiode is a blue photodiode.

10. The image sensor according to claim 8, wherein the second color photodiode is provided over the first color photodiode, and wherein the third color photodiode is provided over the second color photodiode.

11. A method for manufacturing an image sensor, comprising:
forming a photodiode region on a substrate;
forming an interlayer dielectric on the substrate;
forming a trench in the interlayer dielectric over the photodiode region by removing a portion of the interlayer dielectric over the photodiode region; and
forming a microlens in the trench, wherein the microlens fills the trench.

12. The method according to claim 11, further comprising forming a light-blocking layer on the interlayer dielectric.

13. The method according to claim 12, wherein forming the light-blocking layer comprises:
applying a glass paste mixed with at least one black pigment; and
performing a sintering process.

14. The method according to claim 13, wherein applying a glass paste mixed with at least one black pigment comprises applying a glass paste mixed with a Fe—Cr—Co based first black pigment and a Cu—Cr based second black pigment.

15. The method according to claim 14, wherein a mixing ratio of the first black pigment and the second black pigment is about 5:4 by weight.

16. The method according to claim 12, wherein the light blocking layer comprises a green color filter photoresist.

17. The method according to claim 11, wherein forming the microlens in the trench comprises filling a photoresist in the trench through a coating process.

18. The method according to claim 11, wherein forming the trench in the interlayer dielectric comprises:
forming a photoresist pattern on the interlayer dielectric, wherein the photoresist pattern is not present over the photodiode region; and
etching the interlayer dielectric using the photoresist pattern as an etching mask.

19. The method according to claim 11, wherein forming the photodiode region comprises:
forming a first color photodiode on the substrate;
forming a second color photodiode over the first color photodiode; and
forming a third color photodiode over the second color photodiode.

20. The method according to claim 19, wherein the first color photodiode is a red photodiode, the second color photodiode is a green photodiode, and the third color photodiode is a blue photodiode.
